(19) United States
(12) Patent Application Publication
(10) Pub. No.: US 2018/0286993 A1
(43) Pub. Date: Oct. 4, 2018

(54) ELECTRODE ARRANGEMENT AND METHOD OF PRODUCTION THEREOF

(71) Applicant: SOLARPAINT LTD., D.N. Hof Carmel (IL)

(72) Inventor: Eran MAIMON, Kibbutz Ein Harod Meuhad (IL)

(21) Appl. No.: 15/764,562

(22) PCT Filed: Jun. 5, 2016
(86) PCT No.: PCT/IL2016/050576

§ 371 Date: Mar. 29, 2018

Related U.S. Application Data
(60) Provisional application No. 62/236,141, filed on Oct. 2, 2015.

(51) Int. Cl. H01L 31/0224; H01L 31/18

(52) U.S. Cl. CPC H01L 31/022425; H01L 31/18

(57) ABSTRACT

A method for use in producing an electrode arrangement is described. The method comprises providing a first patterned structure, said first patterned structure having a first layer comprising a first electrically conducting material on one face thereof and a layer of an electrically insulating material on one other face thereof. Said first patterned structure comprises a plurality of perforations forming said pattern. Applying a second layer comprising a second electrically conducting material on said electrically insulating material of the first patterned structure thereby covering a face of said first patterned structure. Thus, a pattern is formed of said first and second electrically conducting materials, being insulated between them and exposed to the environment on a second face of said electrode arrangement.

### TECHNOLOGICAL FIELD

The present invention is in the field of manufacturing techniques for producing an electrode arrangement. The invention is specifically related to flexible electrode arrangements capable of bending and suitable for various applications.

### BACKGROUND

Flexible electronic devices, such as flexible displays, sensors, photovoltaic cells, and others, are desirable for various applications. There are many barriers for the introduction of flexible electrical circuits, which are especially manifested in miniaturization of features down to micrometric scale and under, and the alignment of these features.

In this connection, an electrode arrangement generally includes a pair of electrodes configured to be insulated from each other, while each of the electrodes should preferably be configured to be within a certain maximal distance from any effective given location on the panel surface.

There are various configurations of an electrode arrangement, suitable for use in flexible electronics, flexible photovoltaic panels and in other general applications.

WO 2015/083175, assigned to the assignee of the present invention, describes an electrode arrangement and a plurality of micro-structures for use in conversion of a surface to a photovoltaic cell. The electrode arrangement comprises at least two sets of conducting wires, comprising wires with coatings configured to allow selective transmission of charge carriers. The wires are configured for charge collection from a medium in surroundings thereof. The sets of conducting wires are arranged in the form of a grid such that the different wires overlay one another defining a region of charge collection, and are insulated from one another in said region of charge collection.

PCT/IL2015/050588, assigned to the assignee of the present invention, describes an optically active medium and an electrode arrangement, for use in providing a photovoltaic device. The optically active medium comprises a liquid carrier comprising: suspended colloidal structures comprising nucleation assisting particles and optically-active semiconducting structures; and at least one soluble material selected such that when said medium is applied on a surface and the liquid carrier is allowed to evaporate, said at least one soluble material interacts with said colloidal structures to form a continuous polycrystalline film of said optically-active semiconducting structures. The electrode arrangement is configured for collection of charge carriers from a medium interacting with said electrodes. The electrode arrangement comprises at least one pair of first and second electrode elements configured as spaced apart patterned electrode elements installable on and extendable along a surface and being configured for selectively collecting electrons and holes respectively.

### GENERAL DESCRIPTION

As indicated above, various configurations of electrode arrangements are known, utilizing at least a pair of electrode elements insulated between them and configured for covering a surface of predetermined area. Generally, providing an effective coverage of the surface with the at least a pair of electrode elements in addition to maintaining sufficient insulation between the electrode elements, results in a complex assembly and high manufacturing costs. This is as a result of the need for alignment of the different electrode elements with respect to each other.

The technique of the present invention provides for an electrode arrangement and a process for assembly thereof, providing a high surface coverage, with a desired density of the conductive material while eliminating the need for alignment of the different conductive materials (electrode elements) of the electrode arrangement. This enables the production of a desired electrode arrangement to be cost effective and highly scalable for roll-to-roll configurations. Generally, the technique of the present invention provides an electrode arrangement comprising at least a pair of electrode elements being insulated from each other. The electrode elements are configured to provide a surface coverage such that any given point of the surface of the electrode arrangement is within a predetermined maximal distance from the two (or more) electrode elements.

The formed electrode arrangement is typically suitable for use in charge collection from photovoltaic panels/films, and specifically photovoltaic films formed by application of optically active material in a paint form to thereby convert a surface to photovoltaic panel. It should however be noted, that the formed electrode arrangement may be used for various other applications including, but not limited to, photovoltaic devices, batteries, display devices, screens, touch panels, sensors, light emitting diodes (LEDs) and high frequency applications such as RF switches and attenuators. For simplicity, the electrode arrangement is described herein below as designed for the non-limiting application of photovoltaic devices.

According to the present technique, the electrode arrangement may be produced by attaching together two thin layers, each comprising at least first and second electrically conducting materials (such that each thin layer includes at least one electrically conducting material), with an insulating material between them. The layers may be attached by an adhesive layer being either one of the first and/or second electrically conducting materials, the insulating material or a dedicated adhesive layer. Additionally or alternatively the layers may be attached by physical connection resulting from surface shaping between the layers. At least one of the of layers comprising the first and second electrically conducting materials is patterned such that after the layers are attached to each other, the resulting electrode arrangement has a face exposing spaced apart regions of the first and second electrically conducting materials (i.e. corresponding regions of the layers) being separated by insulating boundaries. Thus, generally the technique may comprise providing a first patterned layer comprising at least the first electrically conducting material and coated along at least one face with a layer of an electrically insulating material. For example, the first patterned layer may be formed by a thin patterned sheet comprising a face of the first electrically conducting material (being a single or multi layered structure) coated by a thin layer of electrically insulating material such that the insulating coating may be patterned or not. Thus the first patterned layer comprises at least one insulating face and at least one other electrically conducting layer, which may be internal or external layer (face). Additionally, a layer comprising at least the second electrically conducting material is applied on the insulated face of the first patterned layer. The combined layered structure thereby has a face thereof having spaced apart exposed regions of the first and second electrically conducting materials being regions of the first and second layers, while being insulated between them by boundaries of an insulating material.

It should be noted, as indicated above, that the two layers may be single or multi layered structures configured with the first and second electrically conducting materials at one face thereof respectively. The layers are configured such that the resulting electrode arrangement has a patterned face having spaced apart regions of the first and second electrically conducting materials associated with the first and second layers respectively. Further, in some configurations, the spaced apart regions may be further selectively coated with additional materials. This may be used e.g. when the desired exposed material is fragile and application of sheets thereof in manufacturing process is difficult. For simplicity, the technique of the invention is described herein below referring to first and second layers comprising respectively first and second electrically conducting materials. It should be understood that the first and second layers may comprise additional material forming a multi-layered structure or not.

It should be noted that one or more of the materials forming the first and second layers (e.g. one or both of the first and second electrically conducting materials and/or additional materials of the layers) may be conformable materials. The use of conformable material provides for applying one or more of the layers to assume a negative pattern relative to pattern of a layer/structure it is applied on. This is typically used, as will be described further below, to create a negative pattern relative to the pattern formed by the first layer (comprising the first electrically conducting material and the electrically insulating material applied thereon). In this configuration, the second layer (comprising the second electrically conducting material) may be conformable such as to assume a negative pattern by filling gaps generated by perforations of the pattern of the first patterned layer (first layer and the insulation thereon). This allows application of the electrode arrangement by layering the different layers on top of each other while the layers conform to provide a stacked structure. Preferably the different layers may also utilize malleable materials capable of varying structure of the layers to conform with patterns and vary thickness of the layer, to thereby enable forming a flat surface of the electrode arrangement, having three or more regions including spaced apart regions of the first and second electrically conducting materials separated between them by boundary regions of the electrically insulating material, such that all the regions and boundaries are substantially on the same plane with desired region size and distances between regions.

It should be noted that the electrode arrangement structure, configured as layered and/or interpenetrating layered structure, provides a simple and direct electrical connection to both the first and second electrically conducting layers via the corresponding first and second layers. For example, the pattern of the first electrically conducting layer may be in the form of a mesh or a net having a plurality of connected regions, stripes or lines where the pattern can be defined by holes within the layer. The second electrically conductive layer may be formable such that when pressed against the first patterned layer, grooves are formed around the location of the holes of the pattern and the layer itself remains substantially continuous enabling electrical connection to the plurality of exposed regions. The layer of first or second electrically conductive material, or the insulating material, may also act as an adhesive, holding the three materials together.

Thus, according to a broad aspect of the present invention, there is provided a method for producing an electrode arrangement. The method comprising: providing a first patterned structure, said first patterned structure comprising a plurality of perforations and having a first layer comprising a first electrically conducting material on one face thereof and a layer of an electrically insulating material on one other face thereof; applying a second layer comprising a second electrically conducting material on said electrically insulating material of the first patterned structure thereby covering a face of said first patterned structure, such as to form a pattern of said first and second electrically conducting materials being insulated between them and exposed to environment on a second face of said electrode arrangement.

According to some embodiments, said providing a first patterned structure may comprise providing a first layer in the form of a perforated layer comprising said first electrically conductive material and coating at least one side thereof by an electrically insulating material, thereby providing said first patterned structure having a first electrically conducting face and a second electrically insulating face.

According to some additional embodiments, said providing a first patterned structure comprises providing a perforated (or otherwise permeable) layer of electrically insulating material and coating one side thereof with a first layer comprising said first electrically conducting material, thereby providing said first patterned structure having a first electrically conducting face and a second electrically insulating face.

According to yet some embodiments, said providing a first patterned structure comprises providing a sheet comprising a layer of said first electrically conducting material, coating one side with a layer of said electrically insulating material and generating a plurality of perforations in said sheet.

Generally, said coating one side thereof may comprise coating using material from gas or liquid phase and allowing said coating to solidify. Additionally or alternatively said coating one side thereof may comprise coating using at least one of the following coating techniques: vacuum deposition, wet chemistry, deposition of suspension, wet film casting.

According to some embodiments of the invention, said applying a layer on said electrically insulating material of the first patterned structure comprises applying a layer of selected formable material and pressing said thin sheet onto said perforated sheet.

According to some embodiments said providing a first patterned structure comprises generating a pattern on a substrate by forming a first layer comprising said first electrically conducting material, and coating said pattern with an electrically insulating material on said pattern such that said first patterned structure being on said substrate having an insulating face exposed. In some configurations, said generating a pattern may comprise printing said pattern with said first electrically conducting material from formable or liquid state. Alternatively or additionally said generating a pattern may comprise applying a layer comprising said first electrically conducting material on said substrate and etching a selected pattern from said layer.

Applying the coating of an electrically insulating material on said pattern may comprise providing said electrically insulating material from gas or liquid phase and allowing said electrically insulating material to solidify to a thin layer in suitable conditions. Further, applying a coating of an electrically insulating material on said pattern may comprise using at least one of the following coating techniques: vacuum deposition, wet chemistry, deposition of suspension, wet film casting, spin coating, drop casting, dip coating, anodizing, thermal oxidation, atomic layer deposition, chemical vapor deposition, electrophoretic deposition.

Generally, said applying a second layer comprising said second electrically conducting material on said electrically insulating material may comprise providing a sheet of said second layer and pressing said insulating face of said first patterned layer onto said sheet. The sheet of said second layer may comprise at least one layer of formable electrically conducting material; said pressing generates a negative pattern in said second layer. The at least one layer of formable electrically conducting material may act as an adhesive and attaches to said first layered pattern.

Typically, according to some embodiments, said exposed face of said electrode arrangement may comprise a pattern in the form of a plurality of spaced apart regions of said first and second electrically conductive materials, separated between them by boundary regions of said electrically insulating material. Regions of said first electrically conducting materials may be electrically connected between them by said first layer while being insulated from regions of the said second electrically conducting material. Regions of said second electrically conducting materials may be electrically connected between them by said second layer while being insulated from regions of the said first electrically conducting material.

According to some embodiments of the invention, the method may further comprise applying a selective coating on said second exposed face of the layer to thereby selectively coat regions of said first or second electrically conducting materials. Said selective coating may be applied using one or more of the following techniques: electrodeposition, electroplating, electrophoresis, surface modification such as anodization, sulfurization, chemical halide reaction, chemical bath, spray, ink jet.

The first patterned structure may generally comprise a pattern having a typical feature size between 100 nanometer and 1 centimeter, thereby providing said pattern on said exposed face of the electrode arrangement with spaced apart region being of size between 100 nanometer and 1 centimeter. The pattern on said exposed face of the electrode arrangement may comprise spaced apart regions of said first and second electrically conducting materials being separated between them by insulating boundaries having width between 1 nanometer and 1 centimeter.

According to some embodiments of the invention, at least one of said first and second electrically conducting material may be selected from the group consisting of: metals, organic conductors, semimetals and specifically transition metals, noble metals, conductive polymers, specifically Aluminum, Iron, steel stainless steel, Tin, Titanium, Copper, Zinc and alloys, oxides, nitrides, chalcegonides and halides thereof. At least one of said first and second electrically conducting material may also comprise a carbon based conductor. Such carbon based conductor may comprise at least one of: graphite, graphene, carbon black, carbon fibers, carbon nanotubes, fullerenes and PCBM.

According to some embodiments, the electrically insulating material may comprise at least one of the following: acrylic, silicone, epoxy, poly(methyl methacrylate), polyimide, PTFE, PET, PE, PES, polypropylene, polycarbonate, polystyrene, parylene, spin-on-glass, silane, silica, alumina, magnesia, glass and zirconia.

The so produced electrode arrangement may be in the form of an electrode carrying sheet having thickness between 2 micrometer and 1 centimeter, thereby enabling said electrode carrying sheet to be rollable or foldable.

Said first and second electrically conducting material may be chemically or physically different from each other. The first and second electrically conducting material may be selected to provide electron and hole selective conduction respectively.

The spaced apart regions of at least one of the first and second electrically conducting materials may be further coated to provide selective conduction for electrons or holes.

Generally, according to some embodiments of the invention, different regions of said electrode arrangement on a sheet may be connected in series and in parallel between each other.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 illustrates an electrode arrangement formed according to some embodiments of the present invention;

FIG. 2 shows a flow chart of a method for producing an electrode arrangement according to some embodiments of the present invention;

FIGS. 3A to 3G schematically illustrate formation of an electrode arrangement according to some embodiments of the present invention;

FIGS. 4A to 4C schematically illustrate formation of an electrode arrangement according to some other embodiments of the present invention; and

FIG. 5 illustrates schematically selective coating of one or both of the first and second electrode elements of the formed electrode arrangement according to some embodiments of the present invention.

FIGS. 6A and 6B show scanning electron microscope images of a patterned substrate formed by stretching of PTFE (FIG. 6A) and stretched PTFE coated with Aluminum (FIG. 6B) that can be used as a patterned layer in some embodiments of the present invention;

FIGS. 7A and 7B show scanning electron microscope images of perforated aluminum sheet, patterned by lithography and etching, that can be used as a patterned layer in some embodiments of the present invention;

FIG. 8 shows a scanning electron microscope image of a formable carbon film that can be used in an electrically conductive layer for producing an electrode arrangement according to some embodiments of the present invention;

### DETAILED DESCRIPTION OF EMBODIMENTS

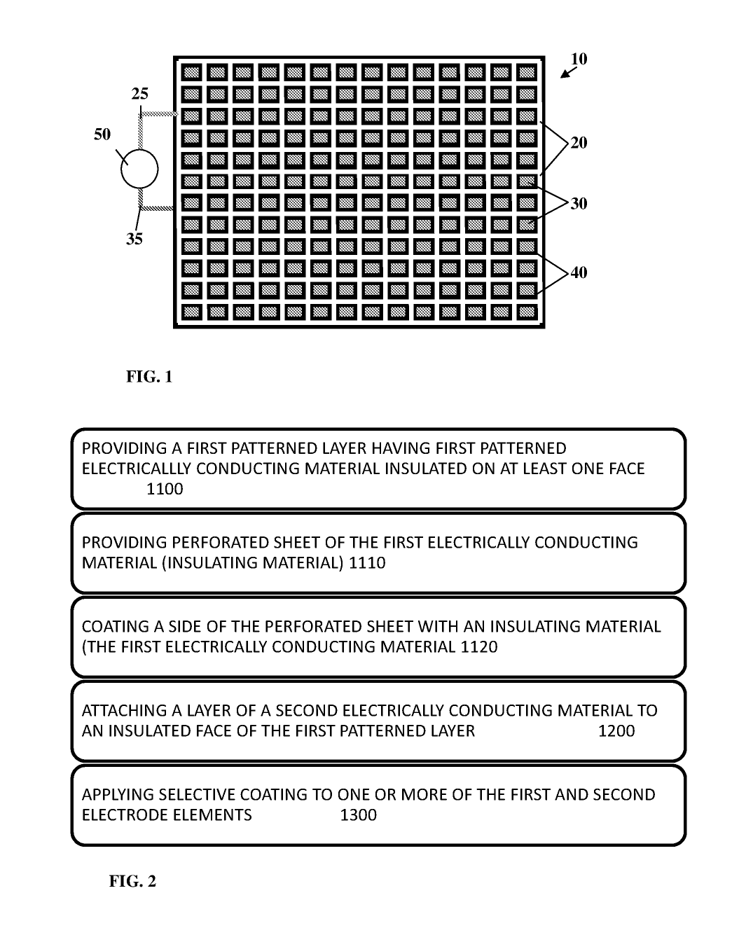

As indicated above, construction and manufacturing of a surface with electrodes, providing both anode and cathode electrode elements or generally two electrode elements, having efficient electrical connection to plurality of points/locations along a surface may be challenging and costly. This is at least due to the need for alignment of the electrode elements in order to avoid creating short circuits between them. The present technique provides for producing an electrode arrangement configured to provide electrical contacts within a desired distance from any point along the surface of the electrode arrangement. Reference is made to FIG. 1 illustrating an example of an electrode arrangement 10, having a pattern of first 20 and second 30 electrode elements, separated between them by insulating boundaries 40. The electrode arrangement may be connectable to a load, battery or power storage/source 50 (receiving energy collected by the electrode arrangement or providing energy thereto) through corresponding power lines 25 and 35 connecting to the first 20 and second 30 electrode elements. The electrode arrangement 10 is configured with at least one face thereof of spaced apart regions of the first 20 and second 30 electrode elements, configured from first and second electrically conducting materials respectively. The spaced apart regions may be of any desired size and geometry (shape) to provide a desired maximal distance from any point along the surface of the electrode arrangement 10 to both the first 20 and second 30 electrode elements. For example, the size of the regions of the second electrode element 30 may be between a few nanometers, e.g. below a micrometer in length, to one centimeter or more. Similarly, the size of the regions of the first electrode element 20 may be between a few nanometers, e.g. below a micrometer in length, to one centimeter or more. Further, the insulating boundaries 40 are preferably thin, typically below one micrometer, however for some applications the boundaries may be from a micrometer and up to a centimeter.

Generally, the electrically insulating material forming the insulating boundaries may be of any suitable insulating material. As described in more details further below, the electrically insulating material may generally be applied from a sheet or coated onto a patterned layer of electrically conducting material. Typically, the electrically insulating material may be any one of: acrylic, silicone, epoxy, poly(methyl methacrylate), polyimide, PTFE, PET, PE, PES, polypropylene, polycarbonate, polystyrene, parylene, spin-on-glass, silane, silica, alumina, magnesia, zirconia, glass, polyurethane and any other suitable material.

Further it should be noted that the geometrical arrangement of the regions of the first 20 and second 30 electrode elements may be of any desired arrangement. For example, the regions of the first electrode element 20 may be along drawing lines of a pattern and the regions of the second 30 electrode arrangement may be within the spaces of the pattern as exemplified in FIG. 1 or vice versa. Alternatively, the regions may be arranged in the form of a chess board. Additionally, the pattern itself may be of any geometrical structure such as including mesh, bee-hive geometry, interdigital arrangement of the regions of the first 20 and second 30 electrode arrangement or in the form of a plate with a plurality of holes or gaps where the plate formed regions of the first electrode element 20 and the holes/gaps form regions of the second electrode element.

The present invention provides a method for fabrication of an electrode arrangement, the process of the invention is configured to provide alignment free fabrication and thereby enable to reduce fabrication costs. Reference is made to FIG. 2 illustrating a basic concept of the fabrication process. As shown, a first patterned layer is provided 1100. The first patterned sheet is configured of a first layer including at least a first electrically conducting material or insulating material 1110, coated from at least one face thereof by an insulating layer or electrically conducting layer 1120. The first layer is generally patterned in the form of a mesh, net or any other pattern having perforations. Additionally, the first layer may be a single or multi-layered structure and is configured such that a face thereof carries a layer of the first electrically conducting material. The pattern of the first layer may be formed in several techniques including printing, lithography and/or etching of material from a continuous layer and other techniques as will be described in more details below.

To provide the regions of the second electrically conducting material, the first patterned layer is attached/pressed onto a second layer configured as a single or multi layered structure and including at least one layer of the second electrically conducting material 1200. Alternatively, a layer of the second electrically conducting material may be formed or deposited on an insulating face of the first patterned layer, with or without additional layers allowing binding of the materials (e.g. adhesive layer). Generally, the 20 second layer may be formed of a formable material, capable of changing structure thereof in response to physical pressure at selected conditions (e.g. predetermined temperature range). This formable material may be the same as the second electrically conducting material, or different therefrom, and so may comprise the second layer in its entirety, or just form a part (internal layer) thereof. The combined multi-layered structure is configured to provide at least one face thereof having exposed spaced apart regions of the first and second electrically conducting materials insulated between them.

In some embodiments, where selected materials are desired, the method further includes applying selective coating to regions of at least one of the first and second electrode elements 1300. Such selective coating may be applied based on intrinsic or externally generated electric potential difference (e.g. chemical potential, voltage applied thereof etc.) between the regions of the first 20 and second 30 electrode elements.

Generally, the first patterned layer may be pre-prepared as a mesh or net sheet having at least one layer of a first electrically conducting material covered by a layer of an electrically insulating material on a second face thereof. As indicated above, the first patterned layer may be formed by a multi-layered structure of the first layer (including the first electrically conducting material) and an insulating layer applied on the first electrically conducting material. Such multilayered structure can be produced by any suitable technique, starting with base layer, and adding additional layers by standard coating methods such as electrodeposition, electroless deposition, vacuum techniques (atomic layer deposition, electron beam deposition, sputtering), blade coating, screen printing, anodizing, chemical vapor deposition, etc. Alternatively, the first patterned layer may be provided using any one of the following techniques:

According to some embodiments the technique includes providing a perforated sheet (e.g. mesh or net) of the first layer (i.e. containing at least the first electrically conducting material). For example, such a sheet may be made of a single conducting material, e.g. like copper, or several layers, some of which conducting, like titanium coated aluminum, with an additional layer of titanium oxide on the titanium. Generally at least one face thereof is formed of the first electrically conducting material (as selected to be exposed in the electrode arrangement). The sheet is preferably configured with strip/line width of between 0.5 micrometer and 1 centimeter, and perforations between the lines of dimension between 0.5 micrometer and 1 centimeter. The sheet is preferably relatively thin and may be of thickness between 0.1 micrometer and 1 millimeter. Applying a layer of an insulating material on a side of the perforated sheet, the insulating layer may be a thin coating allowing insulation between the first and second electrically conducting materials. The insulating layer may be applied by spray coating, pressing of a formable layer, anodizing, SolGel, dip coating, spin coating, electrodeposition, electrophoresis, electroless deposition, vacuum deposition, chemical vapor deposition, atomic layer deposition, tape casting, drop casting, screen printing, slot die coating, etc.

Alternatively, according to some embodiments of the invention, the initially provided perforated layer may be of an electrically insulating material, e.g. acrylic, silicone, epoxy, poly(methyl methacrylate), polyimide, PTFE, PES, polypropylene, polycarbonate, polystyrene, parylene, spin-on-glass, silane, silica, alumina, magnesia, zirconia, glass, polyurethane and any other suitable material. Providing the first patterned layer may include applying a layer of one or more electrically conducting materials (including the first electrically conducting material and possibly layers of insulating or semi-conducting materials) on one face of the insulating perforated layer to form a patterned layer having one electrically conducting face and one electrically insulating face. The application may be by spray coating, SolGel, dip coating, spin coating, electrodeposition, electrophoresis, electroless deposition, vacuum deposition, chemical vapor deposition, atomic layer deposition, tape casting, drop casting, screen printing, slot die coating, etc.

Such a perforated layer, either conducting or insulating, may be obtained by using filters or membranes. Alternatively, the layer may be manufactured by using a starting sheet composed of two or more materials, either where one of the materials is embedded in the others, or a phase separation is induced to create such a configuration. Then the embedded material is disposed of, e.g. by salvation or dissolution, burning, melting, vaporizing, electric or magnetic field, etc. the remaining sheet will have gaps where the material that was disposed of was embedded. For example, polystyrene microspheres may be dispersed in a disposable substrate, and two thin layers (less than the radius of the microspheres), one conductive and the other insulating, e.g. Al and silica, can be deposited by evaporation on the substrate. Thus the spheres are embedded in the evaporated layers. After removing the microspheres, by oxygen plasma for example, and the disposable substrate, we are left with a patterned layer, one side of which is conducting, and the other insulating.

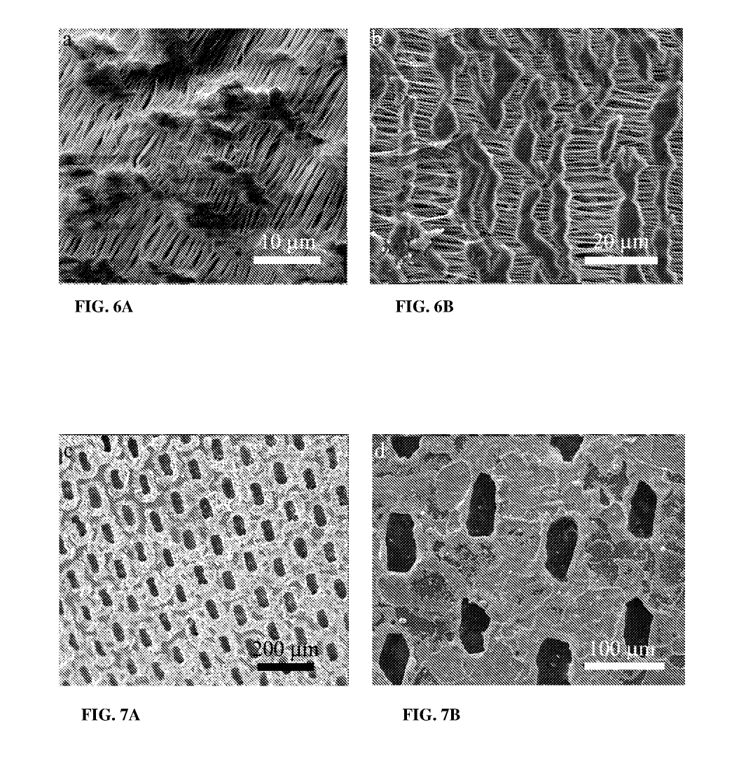

According to some other embodiments the technique may utilize either woven or non woven sheets, such as PET or PTFE membranes, to provide a perforated layer. These sheets may be stretched in a controllable fashion to form holes or gaps as exemplified in FIGS. 6A to 6B. FIG. 6A shows a PTFE membrane that is stretched to form a perforated sheet. The membrane may be electrically insulating, and consists of “islands” of PTFE, connected by thin PTFE strings, which are separated by gaps, forming the desired pattern for the first layer of the electrode arrangement. FIG. 6B shows the stretched membrane after coating by Aluminum (by thermal evaporation) on one side, thus providing a first layer with a conducting face and an insulating face.

According to an additional embodiment of the present method for producing the electrode arrangement, the method may include providing a substrate, preferably disposable or reusable, and applying a pattern of the first electrically conducting material on a surface of the substrate. Applying a layer of electrically insulating material on the pattern and possibly also on the exposed substrate, e.g. by drop casting dip coating or tape casting. The pattern of the first electrically conducting material may be printed in the form of the desired pattern or applied in a complete layer and etched or cut to form the desired pattern.

To form the electrode arrangement, a second layer is applied on the patterned layer. As described above, the second layer may be a single or multi-layered structure and typically includes a layer of the second electrically conducting material configured to be exposed in the electrode arrangement. This second layer may be applied in various techniques as will be described further below. Additionally, it may preferably be applied in a continuous layer to thereby allow exposure of the second electrically conducting material through perforations in the first patterned layer. The applied second layer forms the resulting electrode arrangement as a multi-layer structure having a first electrically conducting patterned layer, an insulating layer configured to prevent electrical transmission between the electrically conducting layers and a second electrically conducting layer generally penetrating through perforations of the first electrically conducting material. On one face thereof, the structure exposes an arrangement of spaced apart regions of the first and second electrically conducting layers on one face thereof, having an insulating layer between the first and second electrically conducting layers, and configured such that electrical connection to the first electrically conducting material can be provided from the first (top) layer of the structure exposing the pattern of spaced apart regions, and electrical connection to the second electrically conducting material can be provided from the second (bottom) layer, being a substantially continuous electrically conducting layer.

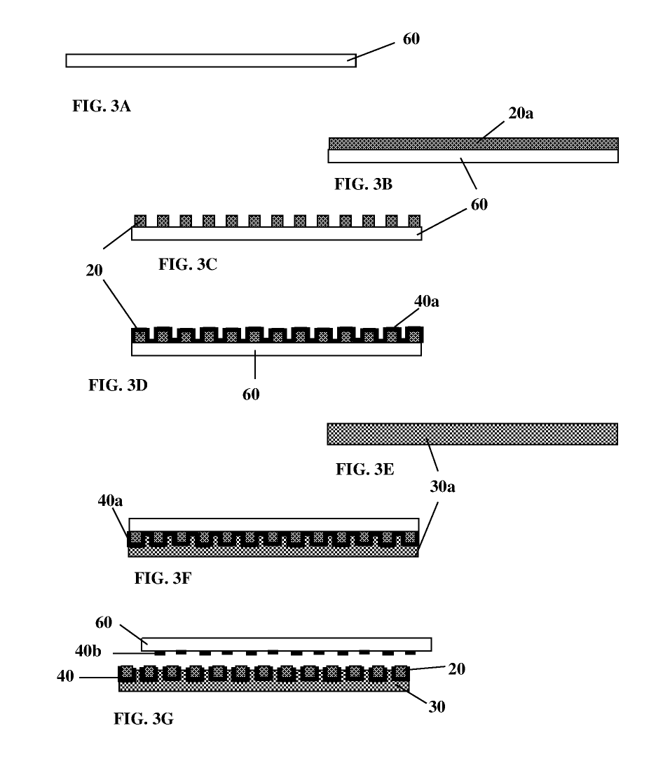

Reference is made to FIGS. 3A to 3G exemplifying a technique for producing an electrode arrangement according to some embodiments of the invention. In FIG. 3A, a substrate 60 is provided as a basis for production of the electrode arrangement. The substrate may be glass or any other suitable material. Additionally, the substrate 60 may be disposable or reusable as the case may be.

A pattern of the first electrically conducting material 20 (FIG. 3C) may be formed by applying a continuous layer of the electrically conducting material 20a, as illustrated in FIG. 3B and selectively etching regions of the continuous layer to form the desired pattern. The layer 20a may be formed by material deposition of a layer including the first electrically conducting material from liquid, gas and/or atomic state. For example, the layer may be formed by electrodeposition, atomic layer deposition etc. Alternatively, the layer 20a may be formed by applying formable material e.g. as a paste on the substrate and allowing it to solidify. The continuous layer 20a is patterned to form perforations in the layer. The patterning may be provided by selective etching of the layer 20a using lithographic techniques, physical etching or any known suitable technique to form a pattern of the first electrically conducting material 20 as shown in FIG. 3C. An exemplary realization of this method is shown in FIG. 7A, and an enlarged image is shown in FIG. 7B. These figures show a perforated substrate, formed by lithography and etching. The face shown in FIG. 7B is electrically conducting Aluminum, and the backside, which is not visible in the image, is electrically insulating polymer (soldering mask). Thus, the substrate shown is a patterned layer having an electrically conducting face and an insulating face.

Alternatively, the first electrically conducting material may be applied onto the substrate 60 to form a pattern 20 without any need for etching. To this end the first electrically conducing material may be printed with the desired pattern on the substrate 60 from liquid or gas phase. In some embodiments, the first electrically conducting material may be selectively deposited, e.g. through a mask, onto the substrate 60.

The resulting pattern 20, shown in FIG. 3C, is preferably in the form of a net, mesh or continuous layer having a plurality of perforations. This allows providing the patterned material to be electrically conducting, and simplify an electrical connection to the first electrically conducting material along the surface of the electrode arrangement.

When the patterned first electrically conducting material is formed and solidifies (or etched), a layer of insulating material 40a is applied onto the pattern and the substrate, as shown in FIG. 3D. The insulating layer 40a may be applied in any suitable technique including spray deposition, deposition from liquid or gas, applying a premade insulating sheet onto the pattern etc. The insulating layer 40a may be applied on the entire surface of the substrate 60 and the electrically conducting pattern 20 thereon, covering the pattern carrying face of the substrate 60 as illustrated in FIG. 3D and/or both faces.

To provide the electrode arrangement, a layer of a second electrically conducting material, 30a in FIGS. 3E and 3F, is applied on the insulating layer 40a. The layer 30a may be deposited on the insulating layer 40a or pressed thereon, to thereby provide the second electrically conducting material within the perforations generated by the pattern of the first electrically conducting material 20. In this connection, a slab of formable electrically conducting material may, e.g. as shown in FIG. 3E, is provided and pressed onto, or being pressed by, the pattern carrying substrate, as illustrated in FIG. 3F. The second electrically conducting material 30a is preferably applied onto the pattern such that the material penetrates into perforations of the pattern while providing a layer that electrically connects the material in the different perforations to form an electrode element along the surface of the pattern.

To expose the regions of the first and second electrically conducting materials 20 and 30, the substrate 60 is removed, together with portions of the insulating material 40b that are deposited on the substrate 60 directly. This provides a face of the electrode arrangement layer structure having exposed spaced apart regions of the first 20 and second 30 electrically conducting materials, insulated between them by a layer of an insulating material 40.

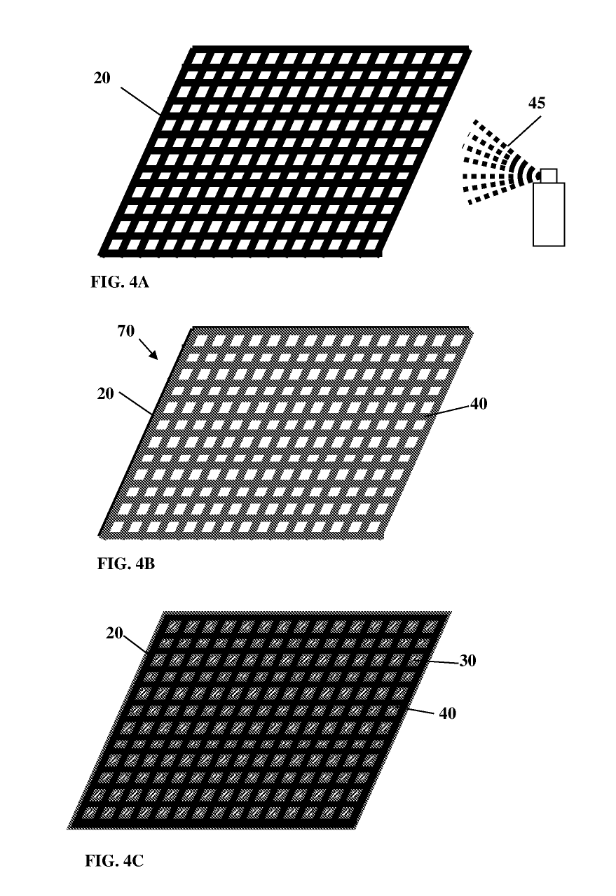

According to some other embodiments of the present invention, the patterned layer may be provided based on an electrically conducting, or electrically insulating, sheet having a pattern in the form of a plurality of perforations. This is exemplified in FIGS. 4A to 4C illustrating an additional embodiment of the present technique for producing an electrode arrangement. As shown in FIG. 4A, a perforated sheet including the first electrically conducting material 20 is provided. The sheet is generally configured as a net or mesh having plurality of perforations of desired dimension surrounded by regions of the layer having desired width. It should be noted that the present technique may also be performed by providing a perforated electrically insulating sheet and coating a face thereof with a layer including the first electrically conducting layer. Both these processes generally result in a similar bi-layer sheet having an electrically conducting face and an electrically insulating face.

According to the present technique, the perforated sheet is coated on one side thereof by a layer of electrically insulating material (for electrically conducting sheet), or by a first layer including the first electrically conducting material (if the initial sheet is insulating). This may be performed by spray 45 as exemplified in the figure, or by deposition by any suitable technique to provide a bi-layered structure 70, as illustrated in FIG. 4B, having a first electrically conducting layer 20 and a layer of an electrically insulating material 40. The bi-layer structure is configured as a perforated sheet in the form of a net or mesh, such that one face thereof exposes the conducting material and another face thereof exposes the electrically insulating material. Generally, the technique may utilize material (electrically insulating or conducting) deposition from liquid or gas onto the perforated sheet, thereby eliminating a need for alignment in the production process.

To provide the resulting electrode arrangement illustrated in FIG. 4C, the technique further includes applying a second layer including the second electrically conducting material 30 onto the electrically insulating face of the patterned structure/layer 70. The second layer may be applied by pressing of the structure 70 onto a slab as described above, by any type of deposition and/or by applying a formable sheet of the second layer on a face of the structure 70. The applied layer (including the second electrically conducting material) 30 is preferably applied to allow material penetration into the perforations of the patterned structure 70 to thereby result in the electrode arrangement having exposed spaced apart regions of the first 20 and second 30 electrically conducting materials.

Generally, the present technique, as described with reference to FIGS. 2, 3A-3G and 4A-4C may be advantageously performed utilizing formable materials for at least one of the first and second layers (e.g. the first and/or second electrically conducting materials), as well as for the insulating materials applied between them. For example: as described in FIG. 3A, the initial pattern of the first electrically conducting layer may be printed on a substrate; a layer of electrically insulating may be deposited from liquid or gas on the pattern of the first electrically conducting layer or on the above described perforated sheet; and the second electrically conducting layer may be pressed onto, or applied/deposited from a pre-prepared sheet, liquid or gas on the electrically insulating face of the patterned structure. More specifically, the formable material may be used in the form of liquid, gas, paste or solid material having formable/plastic properties while capable of solidifying in suitable conditions, e.g. exposure to heat, pressure, UV radiation, etc. Thus, the materials used may allow conforming to a predesigned template, e.g. acting as an adhesive, and then harden in that position and/or configuration.

The use of formable materials in at least one of the first and second electrically conducting materials and the electrically insulating material, as well as the above described production techniques, eliminates, or at least significantly reduces any need for alignment of the elements of the electrode arrangement in the production process. More specifically, the use of material deposition techniques, or materials having formable properties, allows the resulting material to conform to existing patterns. Thus, an electrically insulating material applied on the pattern of first electrically conducting layer, as exemplified in FIG. 3C and FIGS. 4A and 4B, may provide the electrically insulating layer to be perfectly in line with the perforated/patterned structure of the first electrically conducting layer.

The applied electrically insulating material also allows directly pressing or applying the second electrically conducting layer, without a need for alignment, while avoiding creation of short circuits in the electrode arrangement. This allows a cost effective technique suitable for providing a sheet-like electrode arrangement, having a predesigned pattern of first and second electrode elements along the surface of the electrode arrangement.

It should be noted that the present technique, according to some embodiments thereof, may utilize one or more adhesive layers between the first electrically conducting material and the electrically insulating material and/or between the electrically insulating material and the second electrically conducting material. Such one or more adhesive layers are used to hold together the sheets/layers of the electrode arrangement to form a sheet-like electrode arrangement. For example, an adhesive layer may be applied on the perforated sheet or the initial patterned layer prior to application of the corresponding electrically insulating (or electrically conducting material) thereon. It should also be noted that according to some embodiments, the electrically insulating material may be selected to provide adhesive properties in addition to insulating properties. Thus the electrically insulating material may be used as adhesive between the first and second electrically conducting materials. Furthermore, one or both of the first and/or second electrically conducting materials may also include an adhesive layer (as a part of a multi-layered structure or as the corresponding electrically conducting layer that seconds as an adhesive), for example when the electrically conducting material is selected as carbon based electrically conducting, the material may include adhesive resin capable of holding the electrode arrangement structure together.

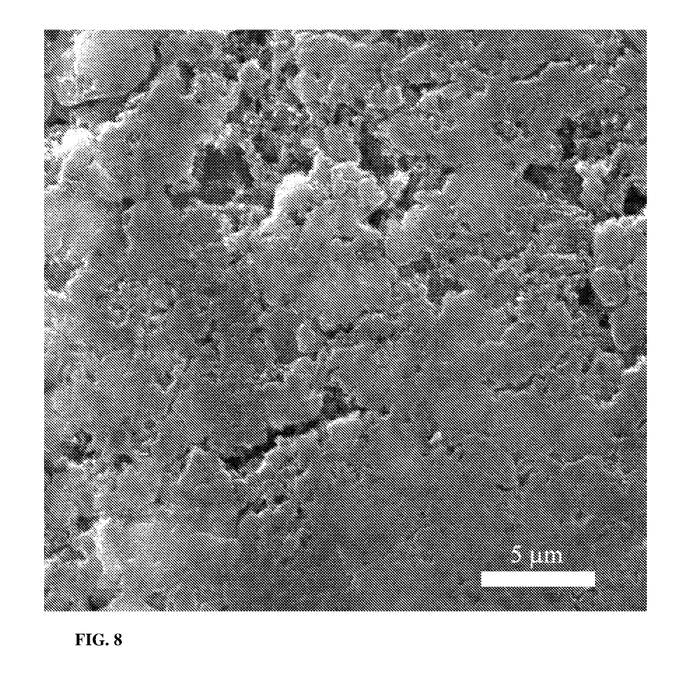

As indicated above, one or more of the first and second layers, or sub-layers thereof in the case of multi-layered structure, may be a formable material used to allow conforming of the applied layers with pattern of a substrate/previous layer. Additionally, the layers may utilize or be formed with adhesive material(s) allowing attachment of the electrode arrangement to provide the electrode arrangement in the form of a multi-layered sheet and thus simplifying the use thereof. An example of a formable adhesive material that may be used in the second electrically conducting layer is polyvinyl acetate (PVAc) based carbon tape. Such PVAc tape is typically formed from a paste that is prepared using 2:1 PVAc and ethyl cellulose, dissolved in ethyl acetate by stirring at temperature of about 80° C. Graphite and carbon black are generally added to the mixture and being milled to provide smooth paste. The resulting paste may then be applied, e.g. by Dr. blade technique, onto a conductive substrate, e.g. Aluminum foil or Tin foil, and allowed to dry. This substrate may be used as a conformable second layer for the electrode arrangement according to the present technique. The carbon on the foil acts as an adhesive by applying pressure onto the insulating face of the first patterned layer, typically in a heated press (e.g. 120° C.). Under heating the PVAc undergoes a plastic deformation, conforming to the pattern of the first layer. After cooling in air the carbon paste hardens again and the multilayered structure may be held together. A microscope image of the dried carbon tape is shown in FIG. 8.

An alternative example is based on the use of commercially available highly conducting carbon tapes, which are typically formable under mild pressure with no need for heating. Such carbon tapes may be taped onto a conducting foil (e.g. Aluminum or Tin) to provide one of the first or second layers. The electrical properties of the carbon tape can be improved by spraying it with a suspension of graphite and carbon black in isopropanol.

Additionally, the technique may utilize a semi-conducting and/or insulating adhesive layer such as succinonitrile, or a mixture of succinonitrile and neopentylglycol or other organic alloy being pristine or doped to modify its conductivity, mechanical robustness and/or their phase transition temperatures. This material can act as an adhesive under mild pressure, and when placed between the layers in the multilayered electrode arrangement it can be used to hold them together, as well as conform into patterns.

In this connection, as indicated above, the present technique provides an electrode arrangement configured to providing electrical connection along a surface. The electrode arrangement may generally use electrodes of first and second electrically conducting materials selected in accordance with desired electrical and chemical properties thereof for a desired application that the electrode arrangement is designed for. The first and second electrically conducting materials used may generally be any conducting materials. This is in addition to other materials that may be used to form the first and/or second layers providing structural stability and/or electrical stability and connection to the exposed electrode regions.

Generally, according to some embodiments, the first and second electrically conducting materials are different from each other. For example, the electrode arrangement may be configured for use with a paint converted photovoltaic panel as described in e.g. patent applications WO 2015/083175 and PCT/IL2015/050588 assigned to the assignee of the present application. In such a configuration, the compositions of the first and second electrically conducting materials are selected in accordance with chemical potential thereof with respect to a selected photoactive material. For example, the first and second electrically conducting materials may be selected such that one material is a P-type conductor and the other is an N-type conductor. Generally, the materials may be selected to provide one of the first and second electrically conducting materials to act as an electron collector, selectively collecting free electrons (or negative charge carriers) and the other one is configured to act as a hole collector, selectively collecting free positive charge carriers. Additionally or alternatively, the regions of the first and/or second electrically conducting materials may be selectively coated with electron- or hole-transport material coating. In this configuration, the first and second electrically conducting materials may be similar, while the appropriate coating is configured to provide charge selectivity in energy collection.

Typically at least one of the first and second electrically conducting materials may be selected to be any conducting material that can be formed into the desired pattern. However, in some embodiments where the first and/or second layers are multi-layered structure, the layer may include additional materials providing formable properties. Generally the first and/or second conducting materials may be selected as any one of metals including transition metals, noble metals, organic conductors, semimetals and conductive polymers. According to some embodiments, the first and/or second electrically conducting materials may be selected from: Aluminum (Al), Iron or steel including stainless steel, Tin (Sn), Nickel (Ni), Silver (Ag), Platinum (Pt), Gold (Au), Titanium (Ti), Copper (Cu), Zinc (Zn) and alloys, oxides, nitrides, Chalcogenides and halides thereof. Additionally, or alternatively, one or both of the first and second electrically conducting materials may be carbon based conductors. For example, one or both of the first and second electrically conducting materials may include any one of graphite, graphene, carbon black, carbon fibers, carbon nanotubes, fullerenes and Phenyl-C61-butyric acid methyl ester (PCBM) material providing an electrically conducting material.

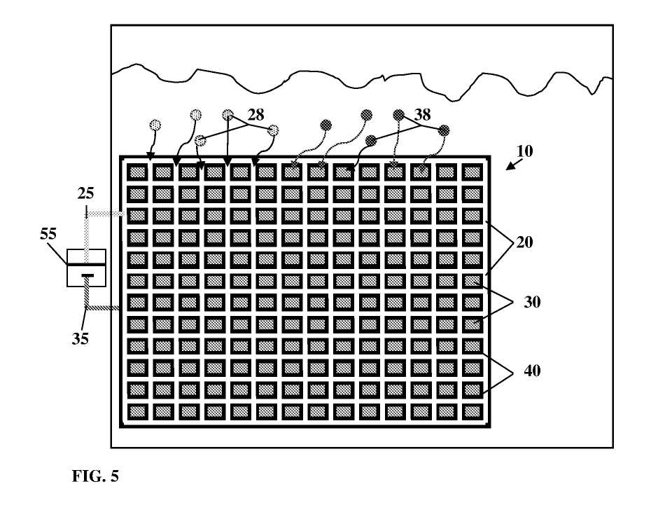

In some embodiments, the present technique provides for selective deposition of different coatings onto the exposed region of the first or second electrically conducting materials when the electrode arrangement is formed. In this connection reference is made to FIG. 5 schematically illustrating selective electrodeposition/electrophoretic deposition of coating materials onto at least one of the first and second electrically conducting regions of the electrode arrangement. Generally, the techniques of electrodeposition, electrophoretic deposition and/or electroplating are well known in the art and will not be described herein in details, other than noting the following. Electrodeposition, electrophoretic deposition and/or electroplating techniques allow for coating selected regions or selected materials while leaving other regions/materials untouched. This may be done is liquid solution environment or in other environments where the coating material 28 and 38 is free to move around the electrode arrangement and to interact or react with selected regions in accordance with chemical or electric potential thereof.

To this end, even in embodiments where the first and second electrically conducting materials are of similar chemical and physical properties, selective coating may be achieved by providing an appropriate electric potential difference between the corresponding electrode elements 20 and 30. To this end a power source 55 may be connected to the first 20 and second 30 electrode elements through corresponding leads 25 and 35. As shown, the electrode arrangement 10 is placed in a container with solution including suitable solutes or colloids. The solutes/colloids 28 and/or 38 may be ions (atomic or molecular ions), molecules, nanomaterials (e.g. nanoparticles or nanorods) or flakes of the desired coating materials, which are attracted to the appropriate regions of the electrode arrangement in response to the applied electric potential thereon. The coating materials may chemically or physically interact with the corresponding one of the first and second electrically conducting layers to form thin coating layer on them.

It should also be noted that the regions of the electrode arrangement may be coated to provide the desired electric conductivity, mechanical strength, chemical and physical stability or any other desired property, as well as achieving the desired manufacturing costs of the electrode arrangement.

For example, the electrode arrangement 10 may be configured with one or both of the first and second electrically conducting material being Tin, Titanium, Copper, Aluminum, Nickel or Zinc. Upon assembly of the electrode arrangement, regions of the first or second electrode elements 20 or 30 may be selectively coated to form an electrode element of oxide over the corresponding metal such as tin oxide over tin, Titania over titanium or ZnO over zinc. In such configurations, according to some embodiments of the invention, the other electrode element's regions may be formed of or coated by a carbon based conductor.

Thus, the technique described here provides for a simple and low cost method for producing an electrode arrangement suitable for use as a surface electrode arrangement having regions of first and second electrode element (e.g. anode and cathode) arranged along a plate-like or sheet electrode arrangement. The method provides a broad material selection and is configured to eliminate, or at least significantly reduce any need for alignment during the production process, thereby significantly reducing complexity and costs. Those skilled in the art will readily appreciate that various modifications and changes can be applied to the embodiments of the invention as hereinbefore described without departing from its scope defined in and by the appended claims.

1. A method for producing an electrode arrangement, the method comprising: providing a first patterned structure, said first patterned structure comprising a plurality of perforations and having a first layer comprising a first electrically conducting material on one face thereof and a layer of an electrically insulating material on one other face thereof; applying a second layer comprising a second electrically conducting material on said electrically insulating material of the first patterned structure thereby covering a face of said first patterned structure, such as to form a pattern of said first and second electrically conducting materials being insulated between them and exposed to environment on a second face of said electrode arrangement.

2. The method of claim 1, wherein said providing a first patterned structure comprises providing a first layer in the form of a perforated layer comprising said first electrically conductive material and coating at least one side thereof by an electrically insulating material, thereby providing said first patterned structure having a first electrically conducting face and a second electrically insulating face.

3. The method of claim 1, wherein said providing a first patterned structure comprises providing a perforated (or otherwise permeable) layer of electrically insulating material and coating one side thereof with a first layer comprising said first electrically conducting material, thereby providing said first patterned structure having a first electrically conducting face and a second electrically insulating face.

4. The method of claim 1, wherein said providing a first patterned structure comprises providing a sheet comprising a layer of said first electrically conducting material, coating one side with a layer of said electrically insulating material and generating a plurality of perforations in said sheet.

5. (canceled)

6. The method of claim 2, wherein said coating one side thereof comprises coating using at least one of the following coating techniques: vacuum deposition, wet chemistry, deposition of suspension, wet film casting.

7. The method of claim 1, wherein said applying a layer on said electrically insulating material of the first patterned structure comprises applying a layer of selected formable material and pressing said thin sheet onto said perforated sheet.

8. The method of claim 1, wherein said providing a first patterned structure comprises generating a pattern on a substrate by forming a first layer comprising said first electrically conducting material, and coating said pattern with an electrically insulating material on said pattern such that said first patterned structure being on said substrate having an insulating face exposed.

9. The method of claim 8, wherein said generating a pattern comprises at least one of: printing said pattern with said first electrically conducting material from formable or liquid state and applying a layer comprising said first electrically conducting material on said substrate and etching a selected pattern from said layer.

10. (canceled)

11. The method of claim 8, wherein applying a coating of an electrically insulating material on said pattern comprises providing said electrically insulating material from gas or liquid phase and allowing said electrically insulating material to solidify to a thin layer in suitable conditions.

12. The method of claim 8, wherein applying a coating of an electrically insulating material on said pattern comprises using at least one of the following coating techniques: vacuum deposition, wet chemistry, deposition of suspension, wet film casting, spin coating, drop casting, dip coating, anodizing, thermal oxidation, atomic layer deposition, chemical vapor deposition, electrophoretic deposition.

13. The method of claim 8, wherein said applying a second layer comprising said second electrically conducting material on said electrically insulating material comprises providing a sheet of said second layer comprising at least one layer of formable electrically conducting material and pressing said insulating face of said first patterned layer onto said sheet, said pressing generates a negative pattern in said second layer.

14. (canceled)

15. The method of claim 13, wherein said at least one layer of formable electrically conducting material acts as an adhesive and attaches to said first layered pattern.

16. The method of claim 1, wherein said exposed face of said electrode arrangement comprises a pattern in the form of a plurality of spaced apart regions of said first and second electrically conductive materials, separated between them by boundary regions of said electrically insulating material.

17. The method of claim 16, wherein regions of said first electrically conducting materials are electrically connected between them by said first layer while being insulated from regions of the said second electrically conducting material and said second electrically conducting materials are electrically connected between them by said second layer while being insulated from regions of the said first electrically conducting material.

18. (canceled)

19. The method of claim 1, further comprising applying a selective coating on said second exposed face of the layer to thereby selectively coat regions of said first or second electrically conducting materials; said selective coating being applied using one or more of the following techniques: electrodeposition, electroplating, electrophoresis, surface modification such as anodization, sulfurization, chemical halide reaction, chemical bath, spray, ink jet.

20. (canceled)

21. The method of claim 1, wherein said first patterned structure comprises a pattern having a typical feature size between 100 nanometer and 1 centimeter, thereby providing said pattern on said exposed face of the electrode arrangement with spaced apart region being of size between 100 nanometer and 1 centimeter.

22. The method of claim 1, wherein said pattern on said exposed face of the electrode arrangement comprises spaced apart regions of said first and second electrically conducting materials being separated between them by insulating boundaries having width between 1 nanometer and 1 centimeter.

23. The method of claim 1, wherein at least one of said first and second electrically conducting material is selected from the group consisting of: metals, organic conductors, graphite, graphene, carbon black, carbon fibers, carbon nanotubes, fullerenes, PCBM, semimetals transition metals, noble metals, and conductive polymers, specifically aluminum, iron, steel stainless steel, tin, titanium, copper, zinc and alloys, oxides, nitrides, chalcegonides and halides thereof.

24-25. (canceled)

26. The method of claim 1, wherein said electrically insulating material comprises at least one of the following: acrylic, silicone, epoxy, poly(methyl methacrylate), polyimide, PTFE, PET, PE, PES, polypropylene, polycarbonate, polystyrene, parylene, spin-on-glass, silane, silica, alumina, magnesia, glass and zirconia.

27. The method of claim 1, wherein said electrode arrangement is in the form of an electrode carrying sheet having thickness between 2 micrometer and 1 centimeter, thereby enabling said electrode carrying sheet to be rollable or foldable.

28. The method of claim 1, wherein said first and second electrically conducting material are chemically or physically different from each other.

29. The method of claim 1, wherein said first and second electrically conducting material are selected to provide electron and hole selective conduction respectively.

30. The method of claim 1, wherein spaced apart regions of at least one of the first and second electrically conducting materials are coated to provide selective conduction for electrons or holes.

31. The method of claim 1, where different regions of said electrode arrangement on a sheet are connected in series and in parallel between each other.
